(19) United States
(12) Patent Application Publication
(10) Pub. No.: US 2013/0328577 A1
(43) Pub. Date: Dec. 12, 2013

(54) CAPACITANCE-TYPE OCCUPANT DETECTION SENSOR

(71) Applicants: Nippon Soken, Inc., Nishio-city (JP); DENSO CORPORATION, Kariya-city (JP)

(72) Inventors: Masayoshi Satake, Okazaki-city (JP); Hiroyuki Mori, Obu-city (JP); Hajime Nakagawa, Nagoya-city (JP)

(73) Assignees: Nippon Soken, Inc., Nishio-city (JP); DENSO CORPORATION, Kariya-city (JP)

(21) Appl. No.: 13/894,745

(22) Filed: May 15, 2013

(30) Foreign Application Priority Data
Jun. 7, 2012 (JP) 2012-130147

(51) Int. Cl. G01R 27/26

(52) U.S. Cl. CPC G01R 27/2605
USPC 324/688; 324/686

(57) ABSTRACT

A capacitance-type occupant detection sensor of the present disclosure detects a vehicle occupant on a seat based on a difference of capacitance between a sensor body and a reference electric potential. The sensor body includes a main electrode and a parallel electrode. The parallel electrode is disposed in parallel with the main electrode with a gap interposed therebetween and has a detection voltage applied thereto. The main electrode and the parallel electrode each have a base material, a first electrode member disposed on the base material, and a second electrode member disposed on the base material to cover the first electrode member, where the second electrode member has an electric conductivity that is lower than the first electrode member. The first electrode member is disposed on a lateral perimeter of the second electrode member to surround a center of the second electrode member.

### CROSS REFERENCE TO RELATED APPLICATION

This application is based on and claims the benefit of priority of Japanese Patent Application No. 2012-130147 filed on Jun. 7, 2012, the disclosure of which is incorporated herein by reference.

### TECHNICAL FIELD

The present disclosure generally relates to a capacitance-type occupant detection sensor used in an automobile.

### BACKGROUND

A capacitance-type occupant detection sensor detects an occupant seated on a seat of the vehicle by detecting a change of capacitance between two electrodes. In order to reduce production cost, in some cases the capacitance-type occupant detection sensor is designed to have its electrodes made of two kinds of materials. For example, Japanese Patent Laid-Open No. 2008-111809 (i.e., patent document 1) discloses a sensor that has silver electrodes made of silver and carbon electrodes made of carbon. The price of the carbon is lower than that of the silver, thereby enabling the reduction of the production cost.

However, in terms of electric conductivity the carbon is lower than the silver. Therefore, due to a greater electric resistance in the carbon electrode, the electric voltage of the carbon electrode that covers the silver electrode is lower than the applied voltage at a portion of the carbon electrode that is far from the silver electrode, or at an edge/periphery portion of the carbon electrode.

When the same voltage is applied to adjacent electrodes, an electric field may be formed between the two adjacent electrodes, since a periphery voltage of the electrode may be lower than the applied voltage. Therefore, the accuracy of the detected electric current may deteriorate, thereby leading to deterioration in accuracy of the detected capacitance as well as to the occupant detection.

### SUMMARY

In an aspect of the present disclosure, a capacitance-type occupant detection sensor detects a vehicle occupant on a seat of a vehicle based on a capacitance value between a reference voltage and a sensor body. The sensor body is disposed in the seat, and includes a main electrode and parallel electrode.

The main electrode and the parallel electrode have a detection voltage applied thereto. The parallel electrode is disposed in parallel with the main electrode with a gap interposed therebetween.

The main electrode and the parallel electrode each have a base material, a first electrode member disposed on the base material, and a second electrode member disposed on the base material to cover the first electrode member. The first electrode member is disposed on a lateral perimeter of the second electrode member to surround a center of the second electrode member. The second electrode member has an electric conductivity that is lower than the first electrode member.

In such a configuration, since the main electrode and the parallel electrode have the first electrode member, which has a high electric conductivity, disposed along its lateral perimeter, the voltage at the periphery of the main electrode and the parallel electrode does not decrease, thereby reducing the unwanted capacitance coupling between the main electrode and the parallel electrode. In other words, at a time of detecting an occupant, the formation of the electric field between the electrodes inside of the sensor body is prevented. Therefore, the capacitance detection accuracy is improved, and, as a result, the occupant detection accuracy is also improved.

In another aspect, the sensor body includes a main electrode, a parallel electrode, and a guard electrode. The main electrode and the parallel electrode have the detection voltage applied thereto, and the guard electrode has the same voltage applied thereto as the detection voltage.

The main electrode has a loop portion and a non-loop portion. The loop portion has a terminating end connected to the main electrode, and the non-loop portion extends from the loop portion.

The parallel electrode is disposed in parallel with the main electrode with a gap interposed therebetween. The parallel electrode is disposed along a first lateral side of the loop portion, and has a starting end and a terminating end positioned on both sides of the non-loop portion.

The guard electrode is arranged to face the main electrode, and has a facing part and a protrusion part. The facing part faces the main electrode and the protrusion part extends from the facing part in a direction away from the parallel electrode, such that the protrusion part extends towards a second lateral side of the loop portion, which is opposite of the first lateral side of the loop portion.

In recent years, a structure having the parallel electrode on both lateral sides (i.e., sides relative to the width) of the main electrode is used for preventing the unwanted capacitance coupling. However, the inventors of the present disclosure found that such structure restricts the shape of the main electrode due to the arrangement of the parallel electrode on both sides of the main electrode. In other words, if the main electrode is configured to have a loop shape, the parallel electrode divided into two parts, i.e., the inner circumference side and the outer circumference side, has to have a complicated structure in order to connect with each other, which may increase the production cost.

On the other hand, if the main electrode is not configured to have the loop shape, the resistance of the main electrode is not reduced, and such resistance in the main electrode leads to the electric potential difference, thereby causing an inaccuracy of the electric current measurement and resulting in the deteriorated accuracy of the capacitance detection and the occupant detection. Therefore, looping of the main electrode without complicating the electrode structure is desired to reduce the influence between the electrodes in the sensor body and avoiding the unwanted capacitance coupling in order to improve the accuracy of the capacitance-type occupant detection sensor at low cost.

The present disclosure enables the reduction of the unwanted capacitance coupling on both sides of the main electrode by providing (i) the parallel electrode on one lateral side (i.e., first lateral side) of the main electrode, and (ii) the protrusion part of the guard electrode on the other lateral side (i.e., a second lateral side) of the main electrode. Further, the parallel electrode is positioned only on one side of the main electrode, which enables the parallel electrode to be arranged in parallel and along the main electrode without complicating the structure, i.e., without splitting the parallel electrode into two parts or the like. Therefore, the inter-electrodes influence in the sensor body is prevented at a low cost, and the capacitance detection accuracy and the occupant detection accuracy is also improved.

In yet another aspect of the present disclosure, a capacitance-type occupant detection sensor includes a sensor body and a detection part. The sensor body is disposed in the seat of the vehicle and includes a main electrode, a parallel electrode, and a guard electrode. The main electrode and the parallel electrode have the detection voltage applied thereto, and the guard electrode has the same voltage applied thereto as the detection voltage.

The parallel electrode is disposed in parallel with the main electrode with a gap interposed therebetween. The guard electrode has a facing part and a sub-guard part. The facing part is arranged to face the main electrode, and the sub-guard part is disposed between the main electrode and the parallel electrode. The facing part and the sub-guard part have the same voltage applied thereto as the detection voltage.

The detection part detects an occupant on the seat based on a capacitance value between the main electrode and a reference electrode. The detection part also detects a liquid spill on the seat based on a capacitance between the main electrode and the parallel electrode when a predetermined voltage is applied to the parallel electrode.

Around the main electrode, the parallel electrode is arranged so that the main and parallel electrodes run in parallel with a gap. By having the same electric potential applied to both of the main and parallel electrodes, the unwanted capacity coupling with a surrounding object by the main electrode is prevented or at least reduced.

Further, the parallel electrode, which has the predetermined electric potential, forms an electric field together with the main electrode, which has the detection voltage applied thereto. The parallel electrode serves as an electrode for detecting the liquid spill based on the capacitance between the main and parallel electrodes. In such manner, the parallel electrode functions as a guard electrode for guarding the periphery of the main electrode and also functions as a spill electrode for detecting the liquid spill.

When the parallel electrode is used as the guard electrode, the guard performance is higher when the parallel electrode is positioned closer to the main electrode. In other words, the occupant detection accuracy is improved when the parallel electrode is closer to the main electrode.

On the other hand, when the parallel electrode is used as the spill electrode, the capacitance change at the liquid spill time is greater, i.e., the sensitivity is improved, when the distance between the main electrode and the parallel electrode is larger to some extent. In other words, the liquid spill detection accuracy is improved when the distance is greater to some extent.

Therefore, improvement of both of the occupant detection accuracy and the water spill detection accuracy is desired.

In yet another aspect of the present disclosure, the main electrode and the parallel electrode are interposed with the sub-guard part of the guard electrode. In such a structure, the sub-guard part has the same electric potential as the guard electrode to be serving as the guard electrode.

In such a structure, the distance between the main electrode and the sub-guard part is enabled to be small, because of the arrangement of the sub-guard part between the main and parallel electrode. That is, the unwanted capacity coupling with the surrounding object is prevented or reduced for the improvement of the occupant detection accuracy.

Further, in such a structure, the distance between the main electrode and the parallel electrode is enabled to be large, because of the arrangement of the sub-guard part. Therefore, the sensitivity for the liquid spill is improved, thereby improving the liquid spill detection accuracy.

The present disclosure having the above structure enables the improvement of both of the occupant detection accuracy and the liquid spill detection accuracy without compromise, based on the prevention of the unwanted capacitance coupling with the surrounding object.

### BRIEF DESCRIPTION OF THE DRAWINGS

Other objects, features and advantages of the present disclosure will become more apparent from the following detailed description disposed with reference to the accompanying drawings, in which:

FIG. 1 is a block diagram of a capacitance-type occupant detection sensor in a first embodiment of the present disclosure;

FIG. 2 is a circuit diagram of the capacitance-type occupant detection sensor of the first embodiment;

FIG. 3 is a top view of a sensor body of the first embodiment;

FIG. 4 is a cross-sectional view of the sensor body along line IV-IV of FIG. 3;

FIG. 5 is a diagram of an electric voltage of a main electrode and a sub-electrode along of the sensor body of the first embodiment;

FIG. 6 is an illustration of an electric line of force formed on the main electrode and the sub-electrode of the sensor body of the first embodiment;

FIG. 7 is a graphical illustration of a comparison example of a capacitance difference generated by a conventional technique versus the sensor body of the first embodiment;

FIG. 8 is a graphical illustration of a change of capacitance of the sensor body of the first embodiment caused by an external factor;

FIG. 9 is a capacitance-type occupant detection sensor of a conventional technique;

FIG. 10 is a circuit diagram of a capacitance-type occupant detection sensor in a second embodiment of the present disclosure;

FIG. 11A is a top view of a sensor body of the second embodiment;

FIG. 11B is an exploded view of the sensor body about XIB of FIG. 11A;

FIG. 12 is a cross-sectional view of the sensor body along line XII-XII of FIG. 11A;

FIG. 13 is a graphical illustration of a resistance value of the main electrode of the sensor body of the second embodiment;

FIG. 14 is a graphical illustration of a comparison example of a capacitance difference generated by a conventional technique versus the sensor body of the second embodiment;

FIG. 15 is a top view of the sensor body illustrating a non-loop portion of the main electrode being positioned inside of a loop portion of the main electrode of the sensor body of the second embodiment;

FIG. 16 top view of the sensor body illustrating a non-loop portion of the main electrode being positioned outside of a loop portion of the main electrode of the sensor body of the second embodiment;

FIG. 17 is a circuit diagram of a capacitance-type occupant detection sensor in a third embodiment of the present disclosure;

FIG. 18 is a top view of the sensor body of the third embodiment;

FIG. 19 is a cross-sectional view of the sensor body along line XIX-XIX of FIG. 18;

FIG. 20 is a graphical illustration of a comparison example of a dry-wet difference of impedance values generated by a conventional technique versus the sensor body of the third embodiment; and

FIG. 21 is a circuit diagram of the capacitance-type occupant detection sensor in a modification of the third embodiment of the present disclosure.

### DETAILED DESCRIPTION

The present disclosure is described in the following with reference to the drawings.

<First Embodiment>

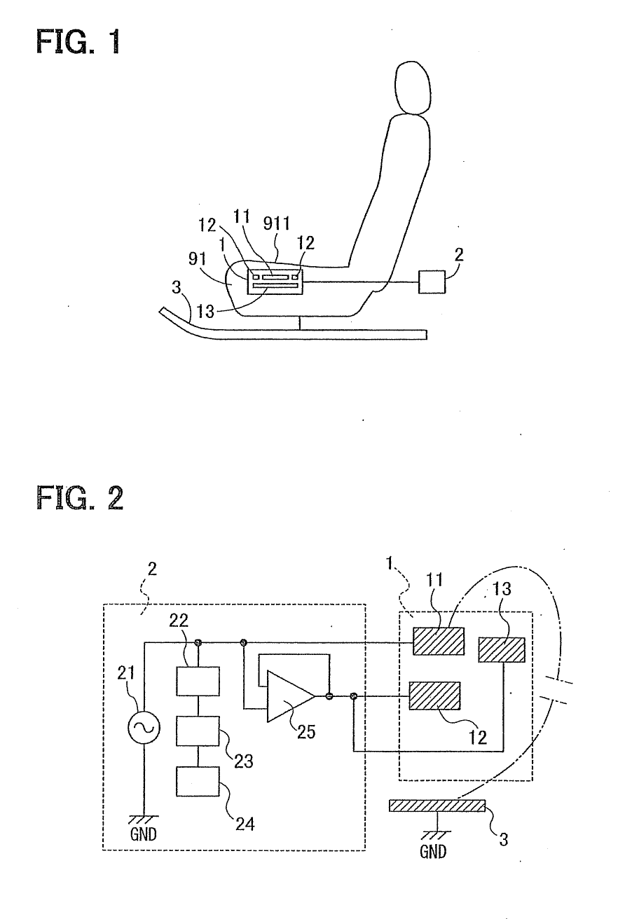

With reference to FIG. 1, the capacitance-type occupant detection sensor in the first embodiment includes a sensor body 1 and an occupant detection ECU 2. The sensor body 1 is a film-shaped sensor mat, in which the electrode has a zigzag shape. The sensor body 1 is disposed in a seat 91 of the vehicle. The sensor body 1 is disposed substantially in parallel with a seat surface 911 of the seat 91.

With reference to FIGS. 2-4, the sensor body 1 includes a main electrode 11, a sub-electrode 12, a guard electrode 13, and film members 14, 15, 16. The main electrode 11 is a flatboard-shaped conductive member, and is disposed on the film member 15. The film member may be provided as a base material.

The sub-electrode 12 is a flat board-shaped conductive member, and is disposed on both sides of the main electrode 11, so that the main electrode 11 and the sub-electrodes 12 are arranged next to each other on the film member 15. In other words, the sub-electrodes 12 are arranged in parallel with the main electrode 11 with a gap interposed between the sub-electrode 12 and a periphery of the main electrode 11. The sub-electrode 12 is arranged along the periphery of the main electrode 11. The main electrode 11 and the sub-electrode 12 are arranged between the film member 14 and the film member 15. The sub-electrode 12 may be referred to as a parallel electrode.

The guard electrode 13 is a flat board-shaped conductive member, and is disposed to face the main electrode 11 with the film member 15 interposed between the main electrode 11 and the guard electrode 13. A film member 16 is disposed on a lower side of the guard electrode 13. In other words, the guard electrode 13 is arranged between the film member 15 and the film member 16.

The film members 14, 15, 16 are made of non-conductive material, such as polyethylene terephthalate (PET), and the film members 14, 15, 16 have an adhesive solution interposed therebetween.

The occupant detection ECU 2 is an electronic control unit, and includes a voltage application part 21, a current detecting part 22, a capacitance detecting part 23, a distinction part 24, and an op-amp 25.

The voltage application part 21 is connected to a vehicle ground GND and to the main electrode 11. The voltage application part 21 is an AC power supply, and applies an alternate voltage (i.e., a detection voltage) to the main electrode 11. In such manner, the main electrode 11 forms an electric field with a vehicle body 3.

The current detecting part 22 is a current sensor, and detects an electric current flowing in the main electrode 11. The electric current is caused by an application of an electric voltage by the voltage application part 21. The capacitance detecting part 23 is connected to the current detecting part 22 and to the distinction part 24. The capacitance detecting part 23 calculates capacitance in the electric field that is formed by the main electrode 11 based on the electric voltage applied by the voltage application part 21 and the electric current detected by the current detecting part 22. The capacitance is calculable based on an imaginary part of an impedance of an electric current path at a time of application of the electric voltage, and the imaginary part is calculable from a phase gap between a phase of the electric current and a phase of the electric voltage.

The distinction part 24 distinguishes, or detects, whether there is an occupant on the seat 91 and whether the occupant is an adult or a child in a child restraint system (CRS) based on a detection result of the capacitance detecting part 23 and a predetermined threshold set in advance.

The op-amp 25 has, on an input side, the voltage application part 21 connected thereto and has, on an output side, the sub-electrode 12 and the guard electrode 13 connected thereto. The op-amp 25 applies, to sub-electrode 12 and the guard electrode 13, an electric voltage that is same as the voltage applied to the main electrode 11. Therefore, the main electrode 11, the sub-electrode 12, and the guard electrode 13 have the same electric potential when the capacitance-type occupant detection sensor is in an occupant detection mode.

The guard electrode 13 prevents a formation of the electric field that is formed by the main electrode 11 and the vehicle body 3 by having the same electric potential as the main electrode 11 on the lower side of the main electrode 11. That is, a formation of the electric field otherwise formed between the main electrode 11 and the vehicle body 3 is prevented by the guard electrode 13, thereby guaranteeing a formation of the electric field by the main electrode 11 only on an upper side of the main electrode 11, i.e., on or above the seat 91 or the seat surface 911.

The sub-electrode 12 is an electrode that prevents an electric line of force to extend from a side portion (i.e., the periphery) of the main electrode to the vehicle body 3 without passing through the seat 91 and the occupant. That is, the sub-electrode 12 prevents a formation of the electric field between the main-electrode 11 and the vehicle body 3, thereby controlling the electric line of force from the main electrode 11 in a horizontal direction.

Therefore, the sub-electrode 12, which has the same electric potential as the main electrode 11, enables a formation of the electric field by the main electrode 11 and the vehicle body 3 in a space above the seat 91, with the electric line of force passing through the seat 91.

The sub-electrode 12 may also be used as an electrode to detect a liquid spill, such as a water spill, on the seat 91. When the sensor is in the liquid spill detection mode, the reference electric potential (i.e., the vehicle GND) is applied to the sub-electrode 12, and an electric field is formed between the main electrode 11, which has the detection voltage applied thereto, and the sub-electrode 12 having the reference electric potential. Based on a capacitance between the relevant electrodes, the liquid spill is detected.

The vehicle body 3 serves as an electrode in addition to be serving as a body of the vehicle, and the vehicle body 3 has the reference electric potential, which is also designated as ground GND.

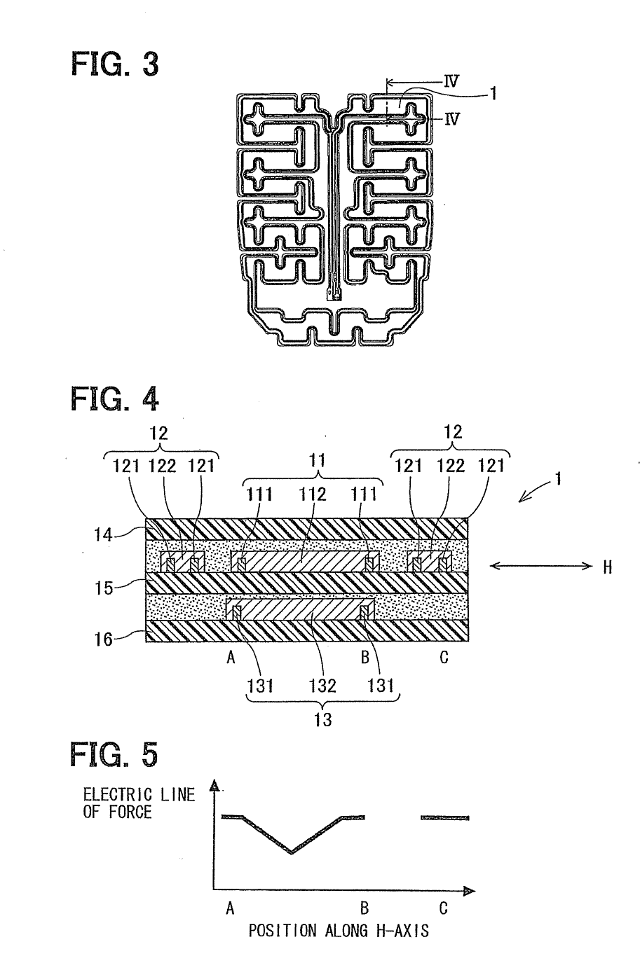

In FIG. 4 provides a view of the sensor body 1 along a horizontal axis (H-axis), where the width of the main electrode 11, sub-electrode 12, and guard electrode 13 is along the H-axis. The main electrode 11 has a silver part 111 that is made of silver and a carbon part 112 that is made of carbon. The silver part 111 may have a rectangular or parallelepiped shape that extends in a rod shape, and is disposed in two parallel lines that extend along an extending direction of the main electrode 11 (e.g., extend along a direction to form the pattern of FIG. 3). The silver part 111 may be referred to as a first electrode member in claims.

The carbon part 112 may extend as a flat-board shape disposed to cover the silver part 111 which forms two lines along the extending direction of the main electrode 11. The carbon part 112 may be referred to as second electrode member in claims. Since the electric conductivity of the carbon is lower than the electric conductivity of the silver, the electric conductivity of the carbon part 112 is lower than the electric conductivity of the silver part 111.

The silver part 111 is covered by the carbon part 112, and is disposed at a lateral perimeter of the carbon part 112 along the H-axis of the main electrode. In other words, the silver part 11 is positioned at both lateral sides of the main electrode 11 along the H-axis, and is within the carbon part 112. The silver part 111 is disposed to surround a center part of the carbon part 112, which is a center part of the main electrode 11. The silver part 111 and the carbon part 112 have a certain voltage applied by the voltage application part 21 in order to have a certain electric potential generated thereon.

Similarly, the sub-electrode 12 is structured to have a silver part 121 and a carbon part 122. The guard electrode 13 is structured to have a silver part 131 and a carbon part 132. The guard electrode 13 has the same dimension as the main electrode 11. The sub-electrode 12 extends parallel with the main electrode 11, and is disposed adjacently on both sides of the main electrode 11 with a gap interposed therebetween. The silver part 121 of the sub-electrode 12 extends in the same direction as the silver part 111 of the main electrode 11, thereby forming two lines in parallel with each other.

The silver parts 121, 131 are similar to the silver part 111, such that the silver parts 121, 131 are covered by the carbon part 122, 132, respectively, and are disposed on a lateral perimeter of the carbon part 122, 132. The silver parts 121, 131 are disposed to surround a center part of the carbon part 122, 132, respectively. In other words, the silver parts 121, 131 are disposed to surround a center part of the sub-electrode 12 and the guard electrode 13, respectively.

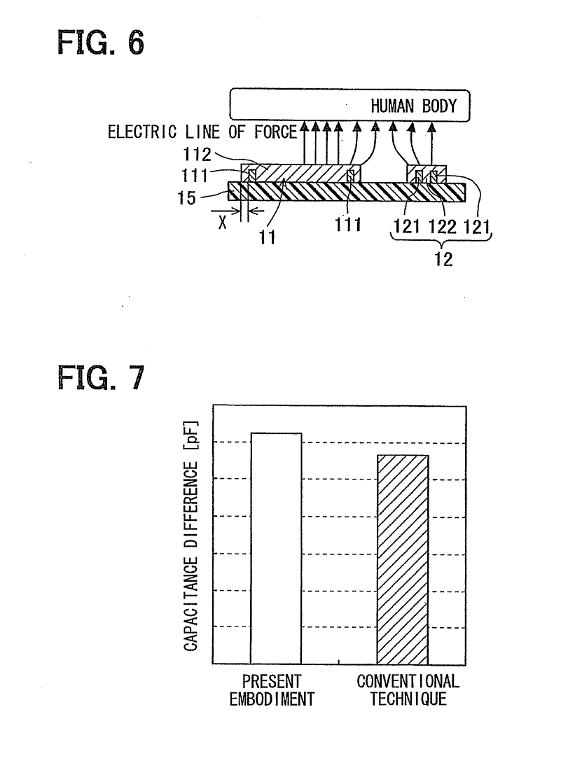

In the present embodiment, all electrodes 11, 12, 13 are configured to have the same distance (i.e., “X” in FIG. 6) between an outer edge of the carbon part 112, 122, 132 and an outer edge of the silver part 111, 121, 131 along the horizontal axis.

According to the configuration of the capacitance-type occupant detection sensor of the present embodiment, the silver parts 111, 121, which have a relatively high electric conductivity, are disposed along the lateral sides of the electrodes 11, 12, respectively. Therefore, as shown in FIG. 5, the electric potential of electrodes 11, 12 is substantially the same as the applied potential at the periphery, and does not have a lower value at the periphery. In particular, “A”, “B”, and “C” of FIG. 5 correspond to the position “A”, “B”, and “C” along the horizontal axis of FIG. 4.

In such manner, a formation of the electric field between the electrodes 11, 12 is prevented, thereby preventing the fluctuation of the electric current value that is detected by the current detecting part 22. In other words, according to the present embodiment, fluctuation of the electric current value is reduced or prevented, and the detection accuracy of the capacitance and the occupant detection is improved.

According to the present embodiment, as shown in FIG. 6, the unwanted capacitance coupling caused by the difference of the electric potentials between the electrodes 11, 12, which are adjacent to each other, is reduced. Further, the silver parts 111, 121 are positioned at the same distance from the outer edge of the electrodes 11, 12, respectively. Therefore, respective peripheries of the electrodes 11, 12 are made to have the same electric potential. Therefore, the unwanted capacitance coupling is further reduced.

As shown in FIG. 7, a difference of capacitance (pF) between an adult sitting value and a one-year old child in the CRS sitting value is shown. In particular, the capacitance-type occupant detection of the present embodiment produces a greater difference of capacitance than that of a conventional technique, such as the conventional technique shown in FIG. 9, where the silver electrode is positioned at the center of the carbon electrode. The capacitance-type occupant detection of the present embodiment improves the accuracy of distinctive detection to distinguish between an adult and a child in a CRS.

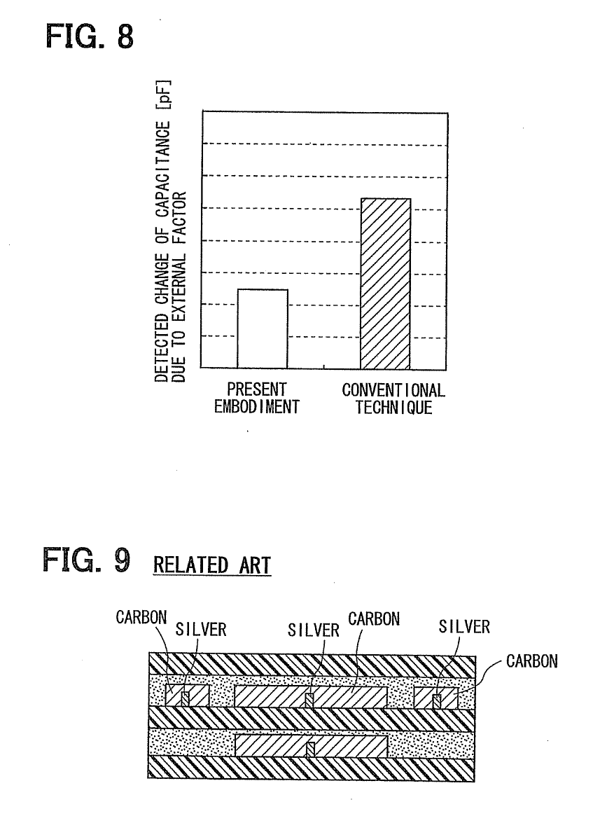

Further, as shown in FIG. 8, the fluctuation of the detection accuracy due to an external factor, such as natural wear, is reduced by half or more. The graph in FIG. 8 illustrates a change of capacitance caused by an external factor such as a wear from normal usage, which is measured by a vertical axis of capacitance (pF). Again, according to the present embodiment, the detection accuracy for detecting an occupant is improved.

The present disclosure is not limited to the above embodiment. For instance, a modification of the above embodiment may be that the sensor body 1 does not have the sub-electrode 12 and a “parallelism with a gap” between two peripheries of the main electrode 11 is arrangement either by having a slit on the periphery or by forming the electrode 11 in a zigzag shape. That is, the two peripheries in parallel may be the peripheries of the same electrode (e.g., the main electrode 11). Such a configuration also prevents a capacitance coupling between the main electrodes 11 because a center of the electrode is surrounded by the silver part 111 that is arranged on the periphery of the electrode.

Further, the sub-electrode 12 may be arranged only on one side of the main electrode 11.

Further, in the present disclosure, the water spill may be detected by using the sub-electrode 12 as described above.

Further, the present disclosure may have a configuration that has the guard electrode 13 omitted therefrom.

Further, the material forming an electrode are not necessarily limited to the above, as long as the electric conductivity of the material of the electrode on the lateral side or lateral perimeter is higher than the electric conductivity of the material covering the electrode on the lateral side or later perimeter.

<Second Embodiment>

The capacitance-type occupant detection sensor in the second embodiment is different from the first embodiment mainly in that the sub-electrode is disposed only on one side of the main electrode, and the guard electrode has a protrusion part.

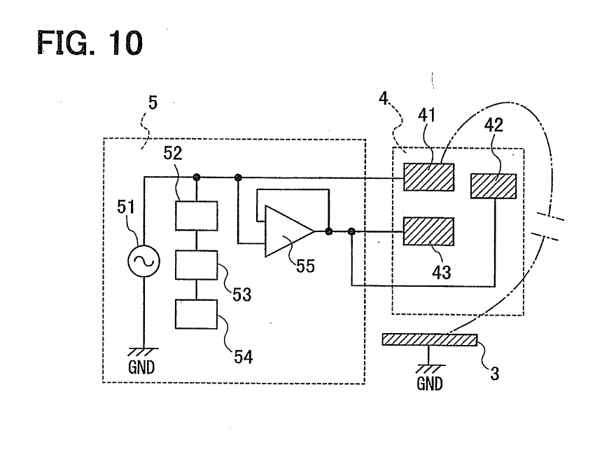

With reference to FIG. 10, the capacitance-type occupant detection sensor in the second embodiment includes a sensor body 4 and an occupant detection ECU 5. The sensor body 4 corresponds to the sensor body having the numeral 1 of FIG. 1.

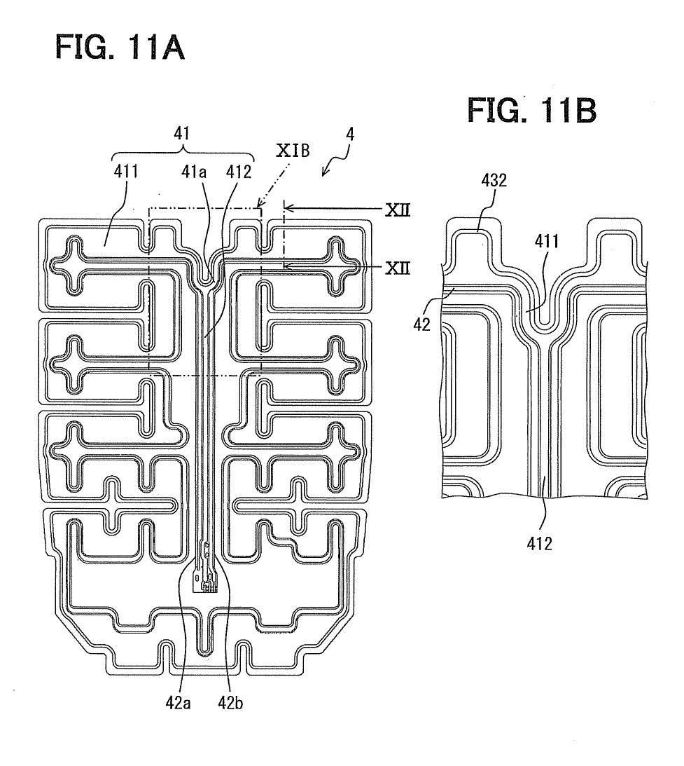

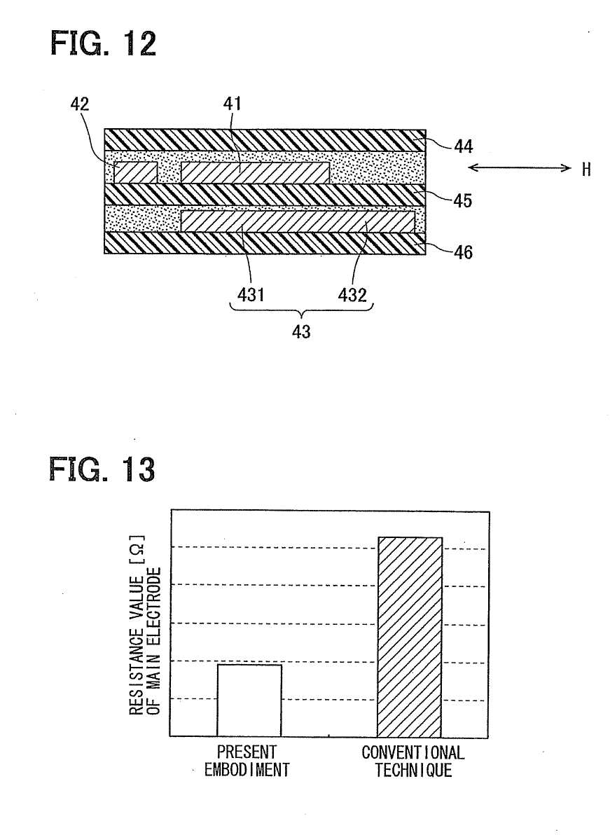

With reference to FIGS. 11A, 11B, and 12, the sensor body 4 is a film-shaped sensor mat, in which the electrode has a zigzag shape. The sensor body 4 is disposed in the seat 91 of the vehicle and is substantially in parallel with the seat surface 911 of the seat 91. The sensor body 4 includes a main electrode 41, a sub-electrode 42, a guard electrode 43, and film members 44, 45 46.

The main electrode 4 is a flat board-shaped conductive member, and is disposed on the film member 45. The main electrode 41 includes a loop portion 411 starting from and ending at an end part 41a, and a non-loop portion 412 having a linear shape that extends from the loop portion 411. The non-loop portion 412 may be arranged inside (i.e., on an inner circumference side), like shown in FIG. 11A, or outside (i.e., on an outer circumference side) of the loop portion 411, and is connected to the occupant detection ECU 5.

The sub-electrode 42 is a flat board-shaped conductive member, and is disposed on the film member 45 next to the main electrode 41, such that the sub-electrode 42 is on one side of the main electrode 41. In particular, in FIG. 12, which shows the sensor body 1 along the H-axis, the sub-electrode 42 is positioned on one side of the mail electrode 41. When viewed from the top, the sub-electrode 42 extends along the inner circumference side (i.e., extends along a lateral side) of the loop portion 411 of the main electrode 41 (FIGS. 11A, 11B). In other words, the sub-electrode 42 is arranged to be next to and in parallel with the loop portion 411 with a gap interposed therebetween. The sub-electrode 42 may be referred to as a parallel electrode in claims.

Along with being disposed on an inside of the loop portion 411, the sub-electrode 42 is arranged on both lateral sides of the non-loop portion 412 as an extension from the inside of the loop portion 411, and is parallel with the non-loop portion 412 with a gap interposed therebetween. A starting end 42a and a terminating end 42b of the sub-electrode 42 are arranged in parallel with an end (i.e., a starting end) of the non-loop portion 412, and are connected to the occupant detection ECU 5. In other words, the starting end 42a of the sub-electrode 42 and the terminating end 42b of the sub-electrode 42 are disposed on the inner circumference side of the loop portion 411.

The film member 44 is placed on the main electrode 41 and the sub-electrode 42. In other words, the main electrode 41 and the sub-electrode 42 are arranged between the film member 44 and the film member 45.

The guard electrode 43 is a flat board-shaped conductive member, and is disposed to face the main electrode 41 with the film member 45 positioned between the main electrode 41 and the guard electrode 43. The film member 46 is disposed under the guard electrode 43, such that the guard electrode 43 is arranged between the film member 45 and the film member 46. The film members 44, 45, 46 are, for example, made of non-conductive material (e.g., PET) and have an adhesive solution interposed therebetween.

With continuing reference to FIG. 12, the guard electrode 43 has a facing part 431 and a protrusion part 432. The facing part 431 faces the main electrode 41 and is aligned under the main electrode with the film member 45 disposed therebetween. The protrusion part 432 extends from the facing part 431, such that it protrudes on the other side of main electrode 41 (i.e., extends in a direction away from the sub-electrode 42 along the H-axis). In particular, when viewed from the top, the protrusion part 432 extends along the outer circumference side (i.e., extends along a lateral side) of the loop portion 411 past the periphery of the main electrode 41, except for the periphery of the corresponding to the non-loop portion 412.

In short, the facing part 431 overlaps with the main electrode 41, and the protrusion part 432 protrudes from a lateral side, which is opposite to the side to which the sub-electrode 42 is arranged relative to the main electrode 41, such that the protrusion part 431 does not overlap with or is not aligned under the main electrode 41. The protrusion part 432 is disposed for a part that at least corresponds to the loop portion 411, and is not disposed for a part that corresponds to the non-loop portion 412 in the present embodiment.

The occupant detection ECU 5 is an electronic control unit, and includes a voltage application part 51, a current detecting part 52, a capacitance detecting part 53, a distinction part 54, and an op-amp 55.

The voltage application part 51 is connected to a vehicle ground GND and to the main electrode 41. The voltage application part 51 is an AC power supply, and applies an alternate voltage (i.e., a detection voltage) to the main electrode 41. In such manner, the main electrode 41 forms an electric field together with the vehicle body 3.

The current detecting part 52 is a current sensor, and detects an electric current flowing in the main electrode 41, which is caused by an application of an electric voltage by the voltage application part 51.

The capacitance detecting part 53 is connected to the current detecting part 52 and to the distinction part 54. The capacitance detecting part 53 calculates capacitance in the electric field that is formed by the main electrode 41 based on the electric voltage applied by the voltage application part 51 and the electric current detected by the current detecting part 52.

The capacitance is calculable based on an imaginary part of an impedance of an electric current path at a time of application of the electric voltage, and the imaginary part is calculable from a phase gap between a phase of the electric current and a phase of the electric voltage.

The distinction part 54 distinguishes, or detects, whether there is an occupant on the seat 91, and whether the occupant is an adult or a child in a CRS based on a detection result of the capacitance detecting part 53 and a predetermined threshold set in advance.

The op-amp 55 has, on an input side, the voltage application part 51 connected thereto and has, on an output side, the sub-electrode 42 and the guard electrode 43 connected thereto. The op-amp 55 applies, to sub-electrode 42 and the guard electrode 43, a voltage that is the same as the voltage applied to the main electrode 41. Therefore, the main electrode 41, the sub-electrode 42 and the guard electrode 43 respectively have the same electric potential when the capacitance-type occupant detection sensor is in an occupant detection mode.

By having the same electric potential as the main electrode 41, the facing part 431 of the guard electrode 43, which is on the lower side of the main electrode 41, prevents a formation of the electric field that is formed by the main electrode 41 and the vehicle body 3. That is, a formation of the electric field by the main electrode 41 in a space other than above the seat 91 or at the seat surface 911 is prevented in such manner. Further, by protruding toward the outer circumference side and having the same electric potential as the main electrode 41, the protrusion part 432 prevents a formation of an electric field by the main electrode 41 toward an outer circumference side of the loop portion 411 and reduces the unwanted capacitance coupling on the outer circumference side. In other words, the protrusion part 432 plays a roll of the sub-electrode 42.

By having the same electric potential as the main electrode 41 on the inner circumference side of the loop portion 411 and on both sides of the non-loop portion 412, the sub-electrode 42 reduces the unwanted capacitance coupling of the main electrode 41 on an inner circumference side of the main electrode 41.

Similar to the first embodiment, the sub-electrode 42 may serve as an electrode to detect the liquid spill.

According to the configuration of the capacitance-type occupant detection sensor in the second embodiment, the terminating end 41a of the main electrode 41 is connected to the main electrode 41 itself to form the loop portion 411, because the main electrode 41 (i.e., the loop portion 411) is guarded on one side and on the other side by different electrodes. In such manner, the unwanted capacitance coupling on both sides of the main electrode 41 is reduced, and the resistance of the main electrode 41 is reduced by having a loop shape, thereby improving the detection accuracy of the capacitance and the occupant detection.

For instance, with reference to FIG. 13, the resistance value of the main electrode 41 in the present embodiment is reduced by 64% relative to a conventional configuration that does not have the loop portion 411.

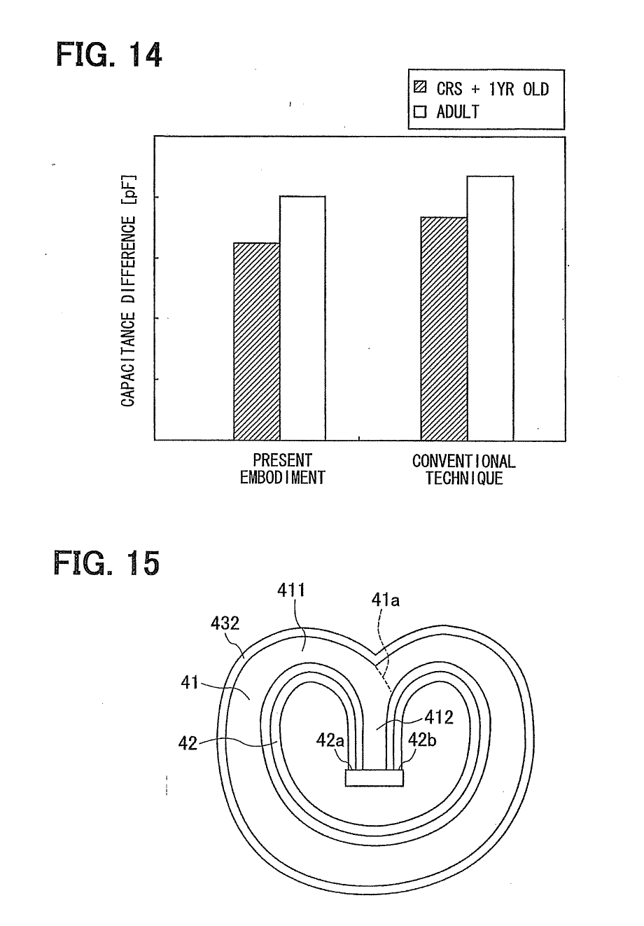

Further, with reference to FIG. 14, in comparison to the conventional technique, the capacitance-type occupant detection sensor of the second embodiment has a greater difference of capacitance (pF) for an adult sitting value and a one-year old child in a CRS sitting value.

In addition, the structure of the sensor is simplified by having the guard electrode 43 protruding from one side, which serves as a substitute of the sub-electrode 42 on such side, thereby preventing the increase of the production cost.

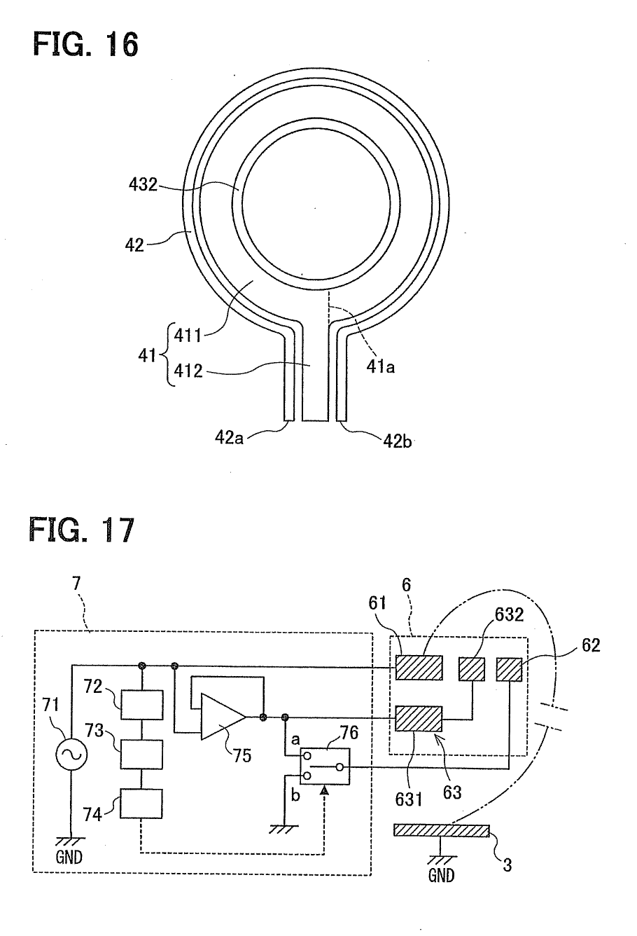

Further, the sub-electrode 42 may be disposed on only one of the inner circumference side or the outer circumference side. In general, the arrangement of the sub-electrode 42 on the inner circumference side of the loop portion 411 is illustrated in FIG. 15, and an arrangement of the sub-electrode 42 on the outer circumference side of the loop portion 411 is illustrated in FIG. 16.

The inner circumference side and the outer circumference side may be referred to as a first lateral side and a second lateral side, respectively, or as a second lateral side and a first lateral side, respectively.

The present disclosure is not limited to the above-described embodiments. For example, a modification of the second embodiment may be that the facing part 431 and the protrusion part 432 of the guard electrode 43 are partially connected, such that a portion of the protrusion part 432, which is not connected to the facing part 431, is arranged in parallel with the facing part 431 with a gap interposed therebetween. In other words, the protrusion part 432 may be disposed along a periphery of the facing part 431 as a separate part, which may be partially connected to the facing part 431.

Further, the starting end may be a connecting part in the sensor body 4 which is connected to the occupant detection ECU 5.

<Third Embodiment>

The capacitance-type occupant detection sensor in the third embodiment is different from the above embodiments mainly in that a sub-guard electrode is disposed in between the main electrode and the sub-electrode electrode.

The capacitance-type occupant detection sensor in the third embodiment includes, as shown in FIG. 17, a sensor body 6 and an occupant detection ECU 7, and the sensor body 6 corresponds to the sensor body having the numeral 1 in FIG. 1.

The sensor body 6 is a film-shaped sensor mat, in which the electrode has a zigzag shape. The sensor body 6 is disposed in the seat 91 of the vehicle, and is substantially in parallel with the seat surface 911 of the seat 91.

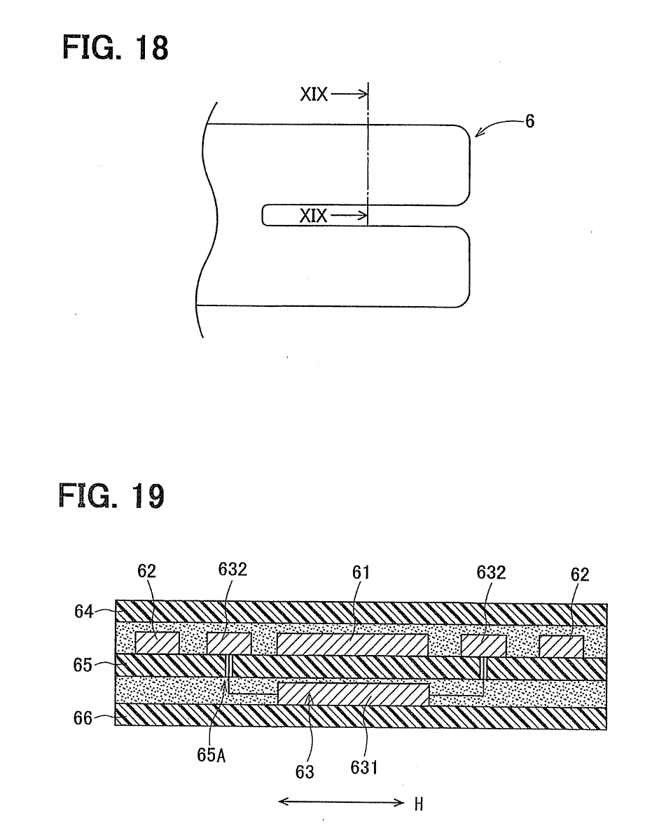

With reference to FIGS. 18-19, the sensor body unit 6 includes a main electrode 61, a sub-electrode 62, a guard electrode 63, and film members 64, 65, 66. The main electrode 61 is a flat board-shaped conductive member, and is disposed on the film member 65.

The sub-electrode 62 is a flat board-shaped conductive member, and is disposed on the film member 65 next to the main electrode 61 and on both sides of the main electrode 61. In other words, the sub-electrode 62 is arranged to be parallel with the main electrode 61 with a gap interposed therebetween. The sub-electrode 62 may be referred to as a parallel electrode in claims.

The film member 64 is disposed on the main electrode 61 and the sub-electrode 62, such that the main electrode 61 and the sub-electrode 62 are arranged between the film member 64 and the film member 65.

The guard electrode 63 is a flat board-shaped conductive member, and has a facing part 631 facing the main electrode 61 and a sub-guard part 632. The film member 66 is disposed under the facing part 631, such that the facing part 631 is arranged between the film member 65 and the film member 66.

The film members 64, 65, 66 may be made of a non-conductive material (e.g., PET), and the film members 64, 65, 66 have an adhesive solution interposed therebetween.

The sub-guard electrode part 632 is electrically coupled to the facing part 631, and is disposed in between the main electrode 61 and the sub-electrode 62 along the periphery of the main electrode 61. In other words, the sub-guard part 632 is disposed on both sides of the main electrode 61, is arranged to be parallel with the main electrode 61, and has a gap interposed therebetween. The sub-guard electrode part 632 has The same electric potential as the facing part 631.

The sub-guard part 632 is disposed between the film member 64 and the film member 65. The sub-guard part 632 and the facing part 631 are electrically connected via a channel 65A, which is formed on the film member 65.

With reference to FIG. 21, the occupant detection ECU 7 is an electronic control unit, and includes a voltage application part 71, a current detecting part 72, a capacitance detecting part 73, a distinction part 74, an op-amp 75, and a switch part 76. The occupant detection ECU 7 may be referred to as a detecting unit in claims.

The voltage application part 71 is connected to the vehicle ground GND and to the main electrode 61. The voltage application part 71 is an AC power supply, and applies an alternate voltage (i.e., a detection voltage) to the main electrode 61. In such manner, the main electrode 61 forms an electric field together with the vehicle body 3.

The current detecting part 72 is a current sensor, and detects an electric current flowing in the main electrode 61, which is caused by an application of an electric voltage by the voltage application part 71.

The capacity detecting part 73 is connected to the current detecting part 72 and the distinction part 74. The capacitance detecting part 73 calculates capacitance in the electric field that is formed by the main electrode 61 based on the electric voltage applied by the voltage application part 71 and the electric current detected by the current detecting part 72.

The capacitance is calculable based on an imaginary part of an impedance of an electric current path at a time of application of the electric voltage, and the imaginary part is calculable from a phase gap between a phase of the electric current and a phase of the electric voltage.

In an occupant detection mode, the distinction part 74 distinguishes, or detects, whether there is an occupant on the seat 91 and whether the occupant is an adult or a child in a CRS based on a detection result of the capacitance detecting part 73 and a predetermined threshold set in advance.

In a spill detection mode, the distinction part 74 detects whether the seat 91 has a liquid spill, such as a water spill, and whether the liquid spill on the seat 91 is salt water or not. The distinction part 74 may performs a similar determination, based on a detection result of the capacitance detecting part 73 and a predetermined threshold set in advance.

The distinction part 74 switches between the occupant detection mode and the spill detection mode based on a predetermined rule (e.g., at a predetermined interval). The distinction part 74 lights a water spill lamp when detecting the water spill, to stop the occupant detection or to perform the occupant detection based on a water spill considered threshold. The distinction part 74 instructs the switch part 76 to switch the detection modes.

The op-amp 75 has the voltage application part 71 connected thereto on an input side, and has the sub-electrode 62 and the guard electrode 63 connected thereto on an output side. In the occupant detection mode, the op-amp 75 applies, to sub-electrode 62 and the guard electrode 63, an electric voltage that is same as the voltage applied to the main electrode 61. Therefore, in the occupant detection mode, the main electrode 61, the sub-electrode 62, and the guard electrode 63 respectively have the same electric potential.

The switch part 76 switches its contact point according to an instruction from the distinction part 74. The switch part 76 changes a connection of the sub-electrode 62 based on an instruction from the distinction part 74 between a contact point ‘a’ that is connected to an output terminal of the op-amp 75 and a contact point ‘b’ that is connected to the vehicle grounding (GND) that is the reference electric potential.

Specifically, the switch part 76 switches a connection of the sub-electrode 62 to (i) the contact point ‘a’ in the occupant detection mode and (ii) to the contact point ‘b’ in the spill detection mode. The sub-electrode 62 has the same electric potential as the main electrode 61 in the occupant detection mode, and has the reference electric potential in the spill detection mode to form an electric field together with the main electrode 61.

The distinction part 74 detects whether the seat 91 has a liquid spill or not based on the capacitance between the main electrode 61 and the sub-electrode 62 in the spill detection mode.

By having the some electric potential as the main electrode 61, the facing part 631 of the guard electrode 63 on the lower side of the main electrode 61 prevents a formation of the electric field that is formed by the main electrode 61 and the vehicle body 3. That is, a formation of the electric field by the main electrode 61 in a space other than above the seat 91 or the seat surface 911 (i.e., under the main electrode 61) is prevented in such manner.

Further, by having the same electric potential as the main electrode 61 on both sides thereof in the H-axis, the sub-guard part 632 prevents a formation of an electric field by a peripheral portion of the main electrode 61 with the vehicle body 3. That is, a formation of the electric field which does not pass through the seat surface 911 of the seat 91 is prevented in such manner.

According to the present embodiment, the sub-guard part 632 is disposed between the main electrode 61 and the sub-electrode 62, and such an arrangement of the sub-guard part 632 at a position close to the main electrode 61 prevents the unwanted capacitance coupling, thereby effectively improving the detection accuracy for detecting an occupant.

By disposing the sub-guard part 632, the sub-electrode 62 is positioned at a moderately far-off position from the main electrode 61. In such manner, a difference of impedance values (i.e., a difference between a value of a dry time when the seat 91 is dry and a value of a spill time when the seat 91 has a water spill) is increased, thereby improving the detection accuracy of the water spill.

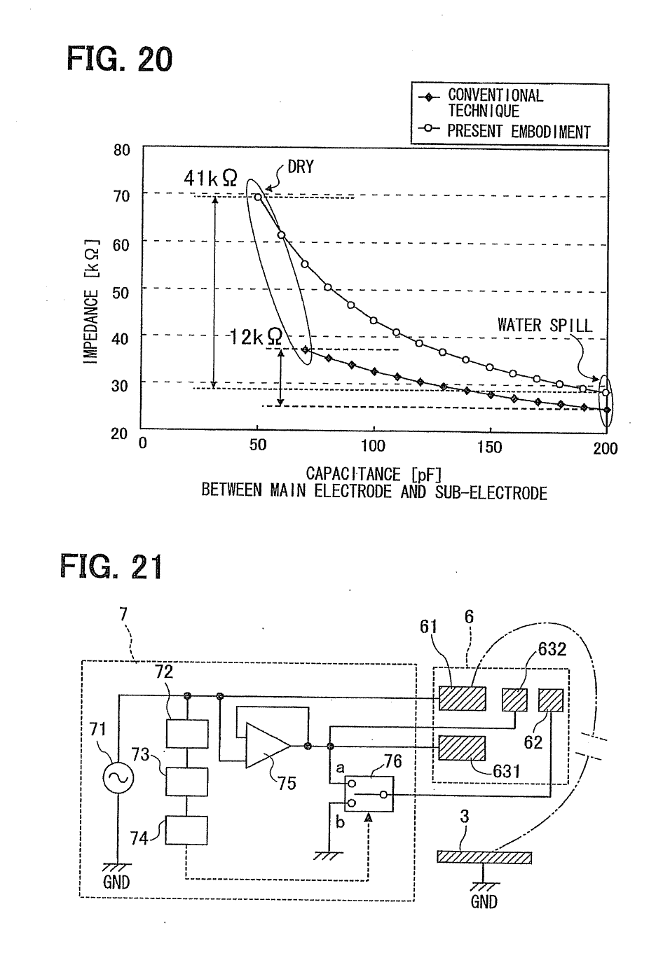

For instance, as shown in FIG. 20, the dry-wet difference of impedance values in the present embodiment is greater than the dry-wet difference of impedance values in the conventional art that does not have the sub-guard part 632. That is, the configuration of the present embodiment enables the improvement of the detection accuracy for both of the spill detection and the occupant detection without compromise, while preventing an influence from the sensor body 6 (i.e., while preventing the unwanted capacitance coupling).

Although the present disclosure has been fully described in connection with the preferred embodiment thereof with reference to the accompanying drawings, it is to be noted that various changes and modifications will become apparent to those skilled in the art.

For instance, the sub-guard part 632 and the facing part 631 may be connected with each other in an inside of the occupant detection ECU 7. Further, as shown in FIG. 21, the detection voltage of the op-amp 75 may be directly applied to the sub-guard electrode unit 632 without passing through the facing part 631.

Further, the first to third embodiments may be arbitrarily combined. By providing the switch part 76 for the first and second embodiments, the sub-electrode may be used as an electrode for the detection of the liquid spill.

Such changes and modifications are to be understood as being within the scope of the present disclosure as defined by the appended claims.

What is claimed is:

1. A sensor body of a capacitance-type occupant detection sensor for detecting an occupant seated on a seat of a vehicle based on a capacitance value between a reference voltage and the sensor body, the sensor body being disposed in the seat, the sensor body comprising:
a main electrode having a detection voltage applied thereto; and
a parallel electrode disposed in parallel with the main electrode with a gap interposed therebetween, the parallel electrode having the detection voltage applied thereto, wherein
the main electrode and the parallel electrode each have a base material, a first electrode member disposed on the base material, and a second electrode member disposed on the base material to cover the first electrode member, the second electrode member has an electric conductivity lower than the first electrode member, and
the first electrode member is disposed on a lateral perimeter of the second electrode member to surround a center of the second electrode member.

2. A sensor body of a capacitance-type occupant detection sensor for detecting an occupant seated on a seat of a vehicle based on a capacitance value between a reference voltage and the sensor body, the sensor body being disposed in the seat, the sensor body comprising:
a main electrode having a detection voltage applied thereto, the main electrode having a loop portion and a non-loop portion, the loop portion having a terminating end connected to the main electrode, and the non-loop portion extending from the loop portion;
a parallel electrode disposed in parallel with the main electrode with a gap interposed therebetween, the parallel electrode having the detection voltage applied thereto, wherein the parallel electrode is disposed along a first lateral side of the loop portion, and has a starting end and a terminating end positioned on both sides of the non-loop portion; and
a guard electrode arranged to face the main electrode and having a same voltage applied thereto as the detection voltage, the guard electrode having a facing part and a protrusion part, wherein the facing part faces the main electrode and the protrusion part extends from the facing part in a direction away from the parallel electrode, such that the protrusion part extends towards a second lateral side of the loop portion, which is opposite of the first lateral side of the loop portion.

3. A capacitance-type occupant detection sensor comprising:
a sensor body disposed in a seat of a vehicle and including:
a main electrode having a detection voltage applied thereto,
a parallel electrode disposed in parallel with the main electrode with a gap interposed therebetween, the parallel electrode having the detection voltage applied thereto, and
a guard electrode having a facing part and a sub-guard part, the facing part arranged to face the main electrode, the sub-guard part disposed between the main electrode and the parallel electrode, and the facing part and the sub-guard part having a same voltage applied thereto as the detection voltage; and
a detection part detecting an occupant on the seat based on a capacitance value between the main electrode and a reference electrode, wherein the detection part detects a liquid spill on the seat based on a capacitance between the main electrode and the parallel electrode when a predetermined voltage is applied to the parallel electrode.
